(19) United States
(12) Patent Application Publication
(10) Pub. No.: US 2025/0329693 A1
(43) Pub. Date: Oct. 23, 2025

(54) SEMICONDUCTOR INTEGRATED CIRCUIT FOR PERFORMING REPAIR OPERATION ON THROUGH-SILICON VIA (TSV)

(71) Applicants: SAMSUNG ELECTRONICS CO., LTD., Suwon-si (KR); UIF (University Industry Foundation), Yonsei University, Seoul (KR)

(72) Inventors: Sungho KANG, Seoul (KR); Seokjun JANG, Seoul (KR); Donghyun HAN, Seoul (KR)

(73) Assignees: SAMSUNG ELECTRONICS CO., LTD., Suwon-si (KR); UIF (University Industry Foundation), Yonsei University, Seoul (KR)

(21) Appl. No.: 19/020,197

(22) Filed: Jan. 14, 2025

(30) Foreign Application Priority Data
Apr. 18, 2024 (KR) 10-2024-0052404
Jun. 13, 2024 (KR) 10-2024-0077163

(51) Int. Cl. H01L 25/065; H01L 21/66

(52) U.S. Cl. CPC H01L 25/0657; H01L 22/22; H01L 2225/06513; H01L 2225/06527; H01L 2225/06541; H01L 2225/06586

(57) ABSTRACT

A semiconductor integrated circuit may include: a first die including a plurality of first through-silicon vias (TSVs), wherein the plurality of first TSVs are divided into TSV repair units, and the TSV repair units include first normal TSVs (NTSVs) for signal transfer and a first redundant TSV (RTSV) for replacing a first failed NTSV from among the first NTSVs; a second die stacked on the first die and including a plurality of second TSVs, wherein the plurality of second TSVs include second NTSVs and a second RTSV for the TSV repair units, and the second NTSVs and the second RTSV are respectively arranged opposite to the first NTSVs and the first RTSV and are respectively connected to the first NTSVs and the first RTSV by electrical connection structures; and a repair circuit.

### CROSS-REFERENCE TO RELATED APPLICATIONS

This application is based on and claims priority under 35 U.S.C. § 119 to Korean Patent Application No. 10-2024-0052404, filed on Apr. 18, 2024, and Korean Patent Application No. 10-2024-0077163, filed on Jun. 13, 2024, in the Korean Intellectual Property Office, the disclosures of which are incorporated by reference herein in their entireties.

### BACKGROUND

### 1. Field

The disclosure relates to semiconductor devices Specifically, the disclosure relates to semiconductor integrated circuits for performing a repair operation on a through-silicon via(s).

### 2. Description of Related Art

3-dimensional (3D) stacking technology is proposed as a solution to overcome a limit to scaling. 3D stacking technology provides a lot of advantages including high capacity, high bandwidths, and small form-factors. 3D semiconductor devices use a through-silicon via (TSV) method in which stacked chips are electrically connected to each other by piercing the stacked chips with silicon vias. TSVs provide communication connections between stacked chips in a vertical direction and are an important factor in 3D stacking. However, when failures (or defects) occur in TSVs, errors may occur in signal transfer through TSVs. TSV defects cause defects of semiconductor devices. Various defects may occur in TSVs. For example, there are void defects because conductive materials fail to completely fill the insides of TSVs, bump contact defects due to the warpage of semiconductor chips or the movement of bump materials, crack defects of TSVs themselves, and the like. It is important to repair defective TSVs for yield and reliability of semiconductor devices.

### SUMMARY

To avoid defects of semiconductor devices due to failed TSVs, redundant TSV (RTSV) design has been proposed. In semiconductor devices, one RTSV may be arranged for every certain number of normal TSVs (NTSVs), and a plurality of routers may be included. When failed NTSVs occur, signal lines of the failed NTSVs may bypass many routers and be repaired with signal lines connected to RTSVs. To construct such a repair path, when many routers are designed to be bypassed, there are issues of hardware overhead and serious timing overhead.

The disclosure provides semiconductor integrated circuits for performing a through-silicon via (TSV) repair operation by using a low-latency switch.

According to one or more example embodiments, a semiconductor integrated circuit may include: a first die including a plurality of first through-silicon vias (TSVs), wherein the plurality of first TSVs are divided into TSV repair units, and the TSV repair units include first normal TSVs (NTSVs) for signal transfer and a first redundant TSV (RTSV) for replacing a first failed NTSV from among the first NTSVs; a second die stacked on the first die and including a plurality of second TSVs, wherein the plurality of second TSVs include second NTSVs and a second RTSV for the TSV repair units, and the second NTSVs and the second RTSV are respectively arranged opposite to the first NTSVs and the first RTSV and are respectively connected to the first NTSVs and the first RTSV by electrical connection structures; and a repair circuit configured to detect defects occurring in the first NTSVs and including first switch circuits connected between the first RTSV and first signal nodes respectively connected to the first NTSVs. The repair circuit may be further configured to cause a first switch circuit that is connected to a first signal node connected to the first failed NTSV, among the first switch circuits, to be enabled and other of the first switch circuits to be disabled.

According to one or more example embodiments, a semiconductor integrated circuit may include: a first die including a plurality of first through-silicon vias (TSVs), wherein the plurality of first TSVs are divided into TSV repair units, and the TSV repair units include first normal TSVs (NTSVs) for signal transfer and a first redundant TSV (RTSV) and a second RTSV for respectively replacing a first failed NTSV and a second failed NTSV from among the first NTSVs; a second die stacked on the first die and including a plurality of second TSVs, wherein the plurality of second TSVs include second NTSVs and a third RTSV and a fourth RTSV for the TSV repair units, and the second NTSVs, the third RTSV, and the fourth RTSV are respectively arranged opposite to the first NTSVs, the first RTSV, and the second RTSV and are respectively connected to the first NTSVs, the first RTSV, and the second RTSV by electrical connection structures; and a repair circuit configured to detect defects occurring in the first NTSVs and including first switch circuits connected between the first RTSV and first signal nodes respectively connected to the first NTSVs, and second switch circuits connected between the second RTSV and the first signal nodes. The repair circuit may be further configured to cause a first switch circuit that is connected to the first failed NTSV of the first NTSVs, among the first switch circuits, and a second switch circuit that is connected to the second failed NTSV of the first NTSVs, among the second switch circuits, to be enabled and others of the first switch circuits and the second switch circuits to be disabled.

According to one or more example embodiments, a method of repairing a through-silicon via (TSV) of a semiconductor integrated circuit, may include: dividing a plurality of first TSVs of a first die into TSV repair units, wherein the TSV repair units include first normal TSVs (NTSVs) for signal transfer and a first redundant TSV (RTSV) for replacing a first failed NTSV from among the first NTSVs; dividing a plurality of second TSVs of a second die stacked on the first die into the TSV repair units, wherein the plurality of second TSVs include second NTSVs and a second RTSV for the TSV repair units, and the second NTSVs and the second RTSV are respectively arranged opposite to the first NTSVs and the first RTSV and are respectively connected to the first NTSVs and the first RTSV by electrical connection structures; detecting the first failed NTSV from among the first NTSVs; and replacing the first failed NTSV by the first RTSV by using first switch circuits connected between the first RTSV and first signal nodes of the first die, the first signal nodes being respectively connected to the first NTSVs. In the replacing of the first failed NTSV by the first RTSV, a first switch circuit that is connected to one of the first signal nodes that is connected to the first failed NTSV, among the first switch circuits, may be enabled and others of the first switch circuits disabled.

According to one or more example embodiments, a semiconductor integrated circuit may include: a first die including a plurality of first through-silicon vias (TSVs), wherein the plurality of first TSVs are divided into TSV repair units, and the TSV repair units include first normal TSVs (NTSVs) for signal transfer and a first redundant TSV (RTSV) for replacing a first failed NTSV from among the first NTSVs; a second die stacked on the first die and including a plurality of second TSVs, wherein the plurality of second TSVs include second NTSVs and a second RTSV for the TSV repair units, and the second NTSVs and the second RTSV are respectively arranged opposite to the first NTSVs and the first RTSV and are respectively connected to the first NTSVs and the first RTSV by electrical connection structures; and a repair circuit including first switch circuits connected between the first RTSV and first signal nodes respectively connected to the first NTSVs and configured to: detect the first failed NTSV; enable one of the first switch circuits that is connected to a first signal node connected to the first failed NTSV; and disable a remainder of the first switch circuits.

### BRIEF DESCRIPTION OF THE DRAWINGS

Embodiments will be more clearly understood from the following detailed description taken in conjunction with the accompanying drawings in which:

FIG. 1 is a diagram illustrating a 3-dimensional (3D) semiconductor integrated circuit (3D IC) based on a through-silicon via (TSV), according to one or more embodiments;

FIG. 2 is a diagram illustrating a 3-dimensional (3D) semiconductor integrated circuit (3D IC) based on a through-silicon via (TSV), according to one or more embodiments;

FIG. 3 is a diagram illustrating an example of the TSV of FIG. 1 according to one or more embodiments;

FIG. 4 is a diagram illustrating a repair circuit for repairing a failed TSV, according to one or more embodiments;

FIG. 5 is a diagram illustrating a repair circuit for repairing a failed TSV, according to one or more embodiments;

FIG. 6 is a diagram illustrating a repair circuit for repairing a failed TSV, according to one or more embodiments;

FIG. 7 is a diagram illustrating a comparative example related to the repair circuit of FIG. 4, according to one or more embodiments;

FIG. 8 is a diagram illustrating a comparative example related to the repair circuit of FIG. 4, according to one or more embodiments;

FIG. 9A illustrates an operation timing diagram of a low-latency switch circuit of FIG. 5, according to one or more embodiments;

FIG. 9B illustrates an operation timing diagram of a 2:1 multiplexer circuit of FIG. 8, according to one or more embodiments;

FIG. 10 is a diagram illustrating a repair circuit for repairing a failed TSV, according to one or more embodiments;

FIG. 11 is a diagram illustrating a repair circuit for repairing a failed TSV,

according to one or more embodiments;

FIG. 12 is a diagram illustrating a repair circuit for repairing a failed TSV, according to one or more embodiments;

FIG. 13 is a diagram illustrating a repair circuit for repairing a failed TSV, according to one or more embodiments;

FIG. 14A is a diagram illustrating a TSV repair unit, according to one or more embodiments;

FIG. 14B is a diagram illustrating a TSV repair unit, according to one or more embodiments; and

FIG. 15 is a block diagram of a system, for illustrating an electronic device including a semiconductor integrated circuit according to one or more embodiments.

### DETAILED DESCRIPTION

As used herein, the term “normal through-silicon via(s) (NTSV(s))” refers to a through-silicon via(s) (TSV(s)) for interfacing signals or power between stacked semiconductor chips, and the term “redundant TSV(s) (RTSV(s))” refers to a through-silicon via(s) (TSV(s)) for interfacing signals or power in place of an NTSV(s) suffering from defects. For convenience of description, an NTSV for signal transmission between semiconductor chips may be referred to as a signal TSV or a main TSV, and an RTSV may be referred to as a repair TSV or an auxiliary TSV.

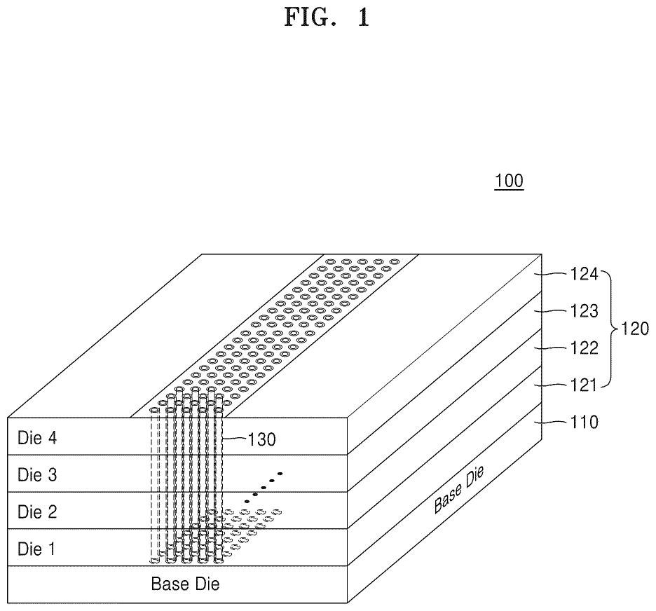

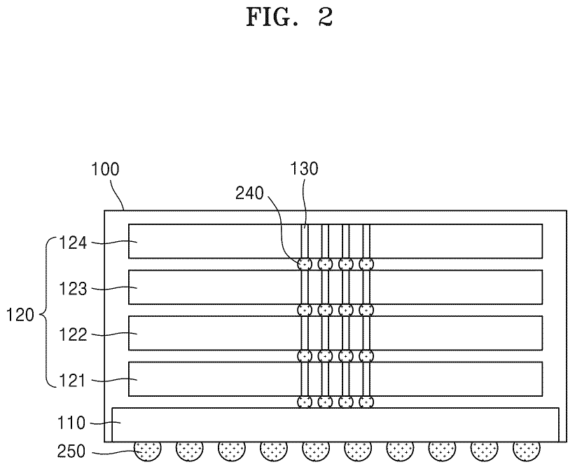

FIGS. 1 and 2 are diagrams illustrating a 3-dimensional (3D) semiconductor integrated circuit (3D IC) based on a TSV. FIG. 2 is a cross-sectional view of a 3D IC 100. For convenience, upper/lower surfaces, upper/lower portions, up/down, and the like are referred to, based on directions illustrated in the accompanying drawings. Therefore, even the same surface may be referred to as an upper surface or a lower surface according to a direction illustrated in a figure.

Referring to FIGS. 1 and 2, the 3D IC 100 may include a plurality of dies that are stacked. The 3D IC 100 may include a memory device and/or a logic semiconductor device. For example, the memory device may include a high-bandwidth memory (HBM) device, and the logic semiconductor device may include a central processing unit (CPU), a graphics processing unit (GPU), a neural processing unit (NPU), an application processor (AP), a system-on-chip (SoC), or the like. The logic semiconductor device may be implemented to be an application-specific integrated circuit (ASIC), an SoC, or the like.

The 3D IC 100 may include a base die 110 and a die stack 120 stacked on the base die 110. The base die 110 may communicate with an external device through conductive means, for example, solder balls 250, formed on the outer surface of the base die 110. The die stack 120 may include TSVs 130 passing through dies (that is, 121 to 124). The TSVs 130 are electrodes obtained by piercing holes in wafers by laser drilling or chemical etching, such as deep reactive ion etching (DRIE), and then filling the holes by plating. First to fourth dies 121 to 124 of the die stack 120 may be electrically connected to each other by the TSVs 130 and bumps (sometimes referred to as microbumps) 240. The bumps 240 are conductive protrusions capable of electrically connecting the first to fourth dies 121 to 124 and the base die 110 to each other.

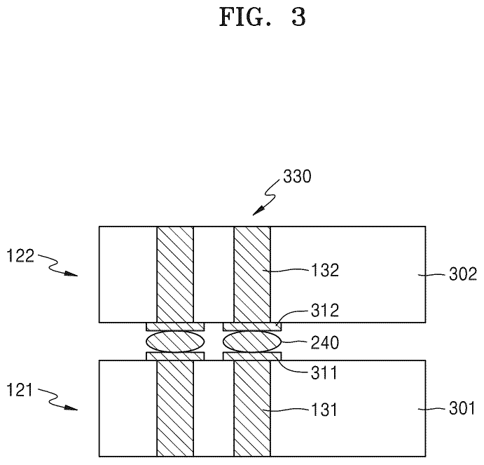

FIG. 3 is a diagram illustrating an example of a TSV of FIG. 1. FIG. 3 illustrates TSVs (that is, 131 and 132) of the first die 121 and the second die 122 of FIG. 1.

Referring to FIGS. 1 and 3, a first die substrate 301 and a second die substrate 302, which are stacked in a vertical direction, are provided. The second die substrate 302 may be arranged on the first die substrate 301. A first TSV 131 may be formed to pass through the first die substrate 301, and a first electrode pad 311 may be formed on the first TSV 131. The first electrode pad 311 may be formed on a surface of the first die substrate 301, the surface being adjacent to the second die substrate 302. A second TSV 132 may be formed to pass through the second die substrate 302, and a second electrode pad 312 may be formed under the second TSV 132. The second electrode pad 312 may be formed on a surface of the second die substrate 302, the surface being adjacent to the first die substrate 301. A bump 240 may be formed between the first electrode pad 311 and the second electrode pad 312. The first die 121 and the second die 122 may be connected to each other by an electrical connection structure 330, which includes the first and second TSVs 131 and 132, the first and second electrode pads 311 and 312, and the bump 240.

During the manufacturing process of the 3D IC 100 or the use of the 3D IC 100, defects may occur in the first and second TSVs 131 and 132. The first and second TSVs 131 and 132 may be signal TSVs (STSVs) for transmitting signals of the 3D IC 100. When defects occur in an STSV(s), a failed STSV(s) may be repaired by an RTSV.

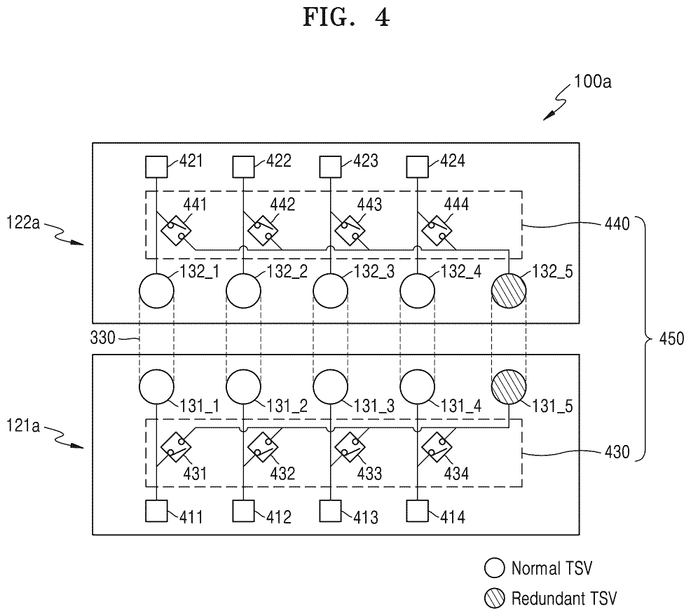

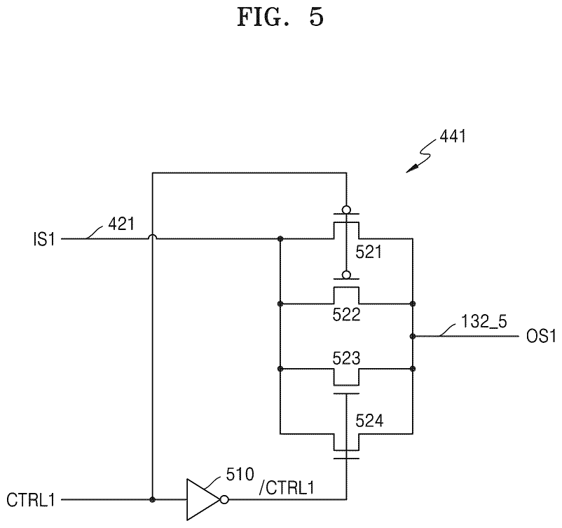

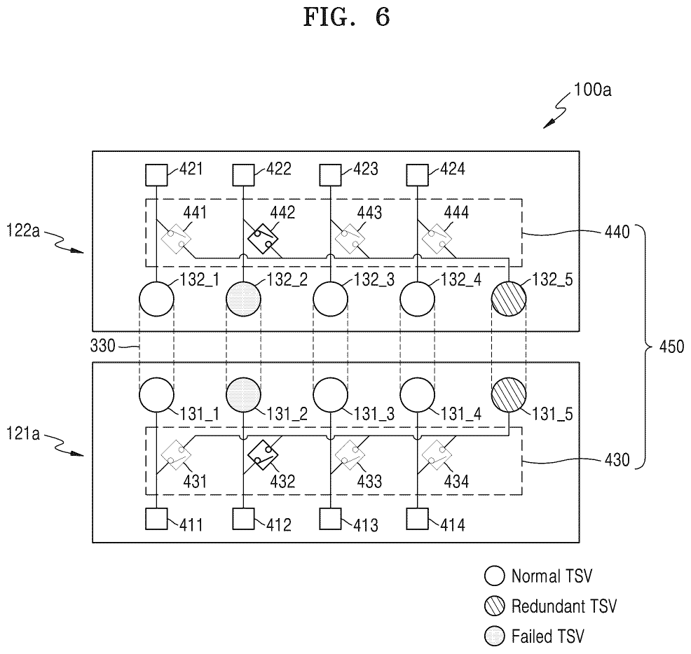

FIGS. 4, 5, and 6 are diagrams illustrating a repair circuit for repairing a failed TSV, according to one or more embodiments. Although FIGS. 4 and 6 illustrate a repair circuit 450 that is included in the first die 121 and the second die 122 in the 3D IC 100 of FIG. 1, the third die 123 and the fourth die 124 of the 3D IC 100 may also include a repair circuit that is substantially identical to the repair circuit 450. FIG. 5 is a diagram illustrating a first switch circuit 441 from among switch circuits (that is, 441, 442, 443, 444, 431, 432, 433, and 434) that are included in the repair circuit 450. Descriptions of the first switch circuit 441 may also be equally applied to the other switch circuits (that is, 442, 443, 444, 431, 432, 433, and 434). Hereinafter, postfixes (for example, “a” in 100a or “a” in 121a) attached to the same reference numeral in different figures are for distinguishing a plurality of components performing similar or same functions.

Referring to FIGS. 1 and 4, in a 3D IC 100a, a first die 121a may include a plurality of TSVs (that is, 131_1, 131_2, 131_3, 131_4, and 131_5). In the first die 121a, the plurality of TSVs (that is, 131_1, 131_2, 131_3, 131_4, and 131_5) may include four NTSVs (that is, 131_1, 131_2, 131_3, and 131_4) and one RTSV 131_5. A second die 122a may include a plurality of TSVs (that is, 132_1, 132_2, 132_3, 132_4, and 132_5). In the second die 122a, the plurality of TSVs (that is, 132_1, 132_2, 132_3, 132_4, and 132_5) may include four NTSVs (that is, 132_1, 132_2, 132_3, and 132_4) and one RTSV 132_5. The TSVs (that is, 132_1, 132_2, 132_3, 132_4, and 132_5) of the second die 122a may be arranged opposite to the TSVs (that is, 131_1, 131_2, 131_3, 131_4, and 131_5) of the first die 121a.

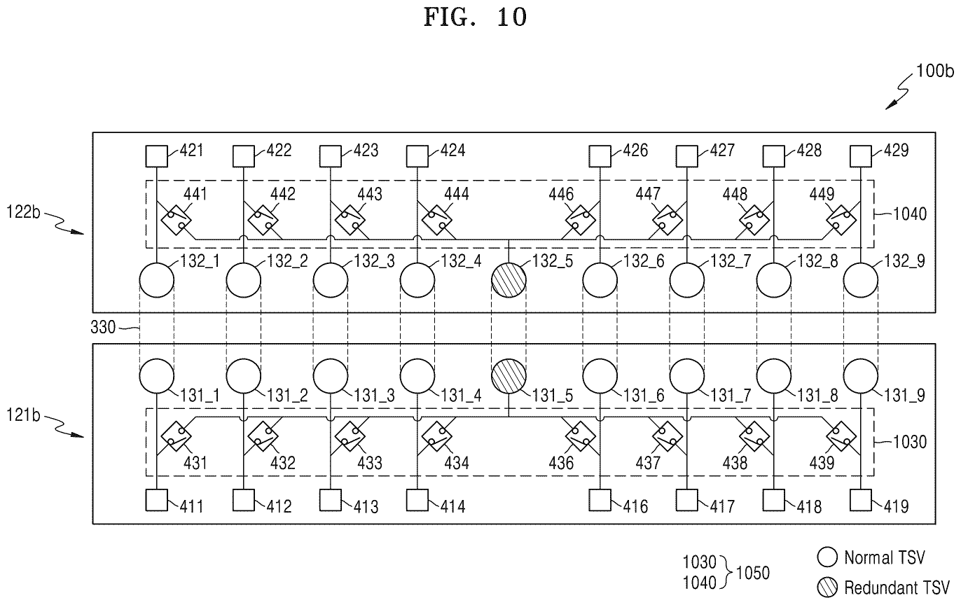

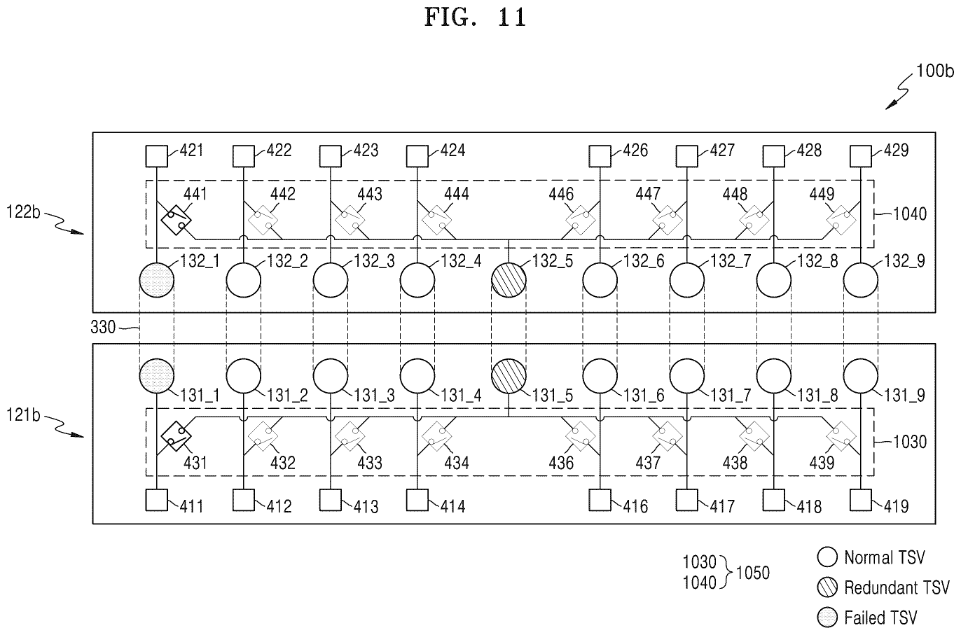

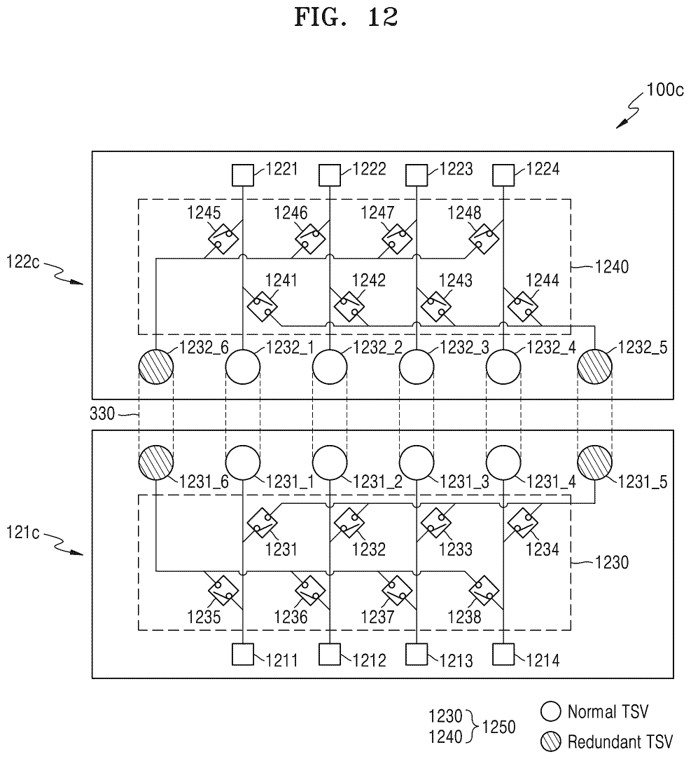

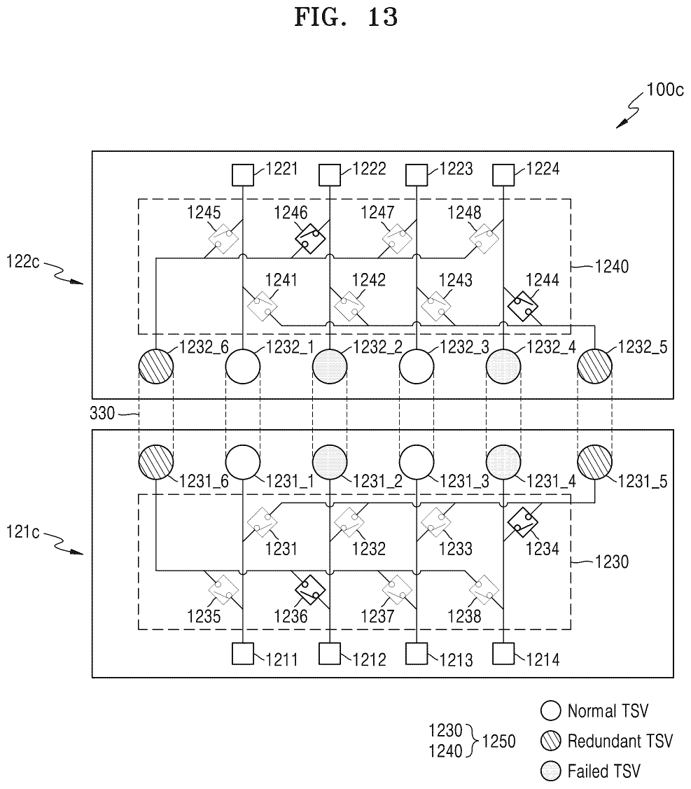

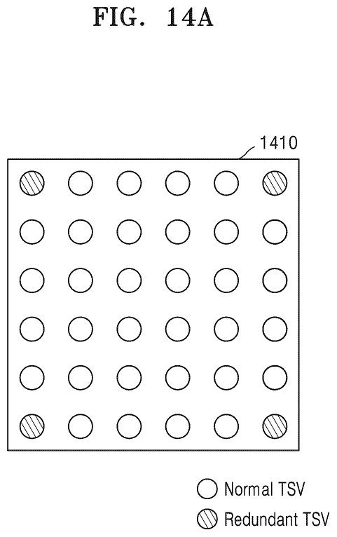

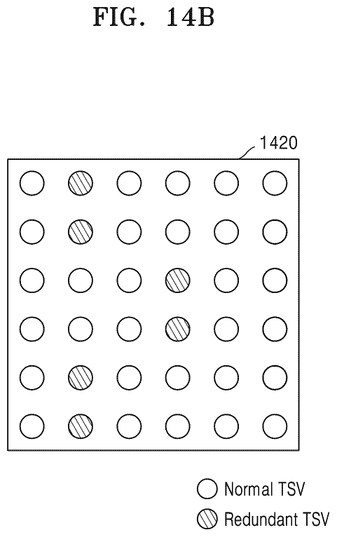

In one or more embodiments, each of the TSVs (that is, 131_1, 131_2, 131_3, 131_4, and 131_5) of the first die 121a may be connected to each of the TSVs (that is, 132_1, 132_2, 132_3, 132_4, and 132_5) of the second die 122a by the electrical connection structure 330 (see FIG. 3). Accordingly, one set including four NTSVs and one RTSV may constitute a TSV repair unit. This means that, when one of the four NTSVs fails, the one failed NTSV may be repaired by the one RTSV. However, this is only a nonlimiting example for description, and the number of NTSVs and the number of RTSVs in the TSV repair unit may be variously designed by taking into account a repair rate. The TSV repair unit may include n NTSVs (where n is a natural number that is at least 2) and m RTSVs (where m<n). For example, the TSV repair unit may be variously implemented by a set (see FIGS. 10 and 11) including 8 NTSVs and 1 RTSV, a set (see FIGS. 12 and 13) including 4 NTSVs and 2 RTSVs, a set (see FIG. 14A) including 32 NTSVs and 4 RTSVs, a set (see FIG. 14B) including 30 NTSVs and 6 RTSVs, or the like.

The first die 121a and the second die 122a may include a repair circuit 450 for repairing a failed TSV. The repair circuit 450 may include a first switching circuit 440 and a second switching circuit 430. Here, the first switching circuit 440 may be included in the second die 122a, and the second switching circuit 430 may be included in the first die 121a. The first switching circuit 440 may be connected between the RTSV 132_5 and signal nodes (that is, 421, 422, 423, and 424) of the second die 122a. The second switching circuit 430 may be connected between the RTSV 131_5 and signal nodes (that is, 411, 412, 413, and 414) of the first die 121a. The signal nodes (that is, 421, 422, 423, and 424) of the second die 122a may be connected to circuit elements (for example, a logic circuit, a transistor, and the like) of the second die 122a or to TSVs 130 of the third die 123.

In the present embodiment, an operation of transmitting a signal from the second die 122a to the first die 121a is described. The signal nodes (that is, 421, 422, 423, and 424) of the second die 122a may function as input signal nodes, and the signal nodes (that is, 411, 412, 413, and 414) of the first die 121a may function as output signal nodes. Therefore, the signal nodes (that is, 421, 422, 423, and 424) of the second die 122a may be referred to as input signal nodes (that is, 421, 422, 423, and 424), and the signal nodes (that is, 411, 412, 413, and 414) of the first die 121a may be referred to as output signal nodes (that is, 411, 412, 413, and 414). In addition, the first switching circuit 440 may be referred to as an input switching circuit 440, and the second switching circuit 430 may be referred to as an output switching circuit 430. For convenience of description, the TSVs (that is, 131_1, 131_2, 131_3, 131_4, and 131_5) of the first die 121a may be referred to as upper TSVs (that is, 131_1, 131_2, 131_3, 131_4, and 131_5), and the TSVs (that is, 132_1, 132_2, 132_3, 132_4, and 132_5) of the second die 122a may be referred to as lower TSVs (that is, 132_1, 132_2, 132_3, 132_4, and 132_5).

In the second die 122a, the input signal nodes (that is, 421, 422, 423, and 424) may be respectively connected to the upper NTSVs (that is, 132_1, 132_2, 132_3, and 132_4). A first input signal node 421 may be connected to a first upper NTSV 132_1, a second input signal node 422 may be connected to a second upper NTSV 132_2, a third input signal node 423 may be connected to a third upper NTSV 132_3, and a fourth input signal node 424 may be connected to a fourth upper NTSV 132_4. The first switching circuit 440 may include switch circuits (that is, 441, 442, 443, and 444) connected between the upper RTSV 132_5 and each of the input signal nodes 421, 422, 423, and 424. A first switch circuit 441 may be connected between a first input signal node 421 and the upper RTSV 132_5, and a second switch circuit 442 may be connected between a second input signal node 422 and the upper RTSV 132_5, a third switch circuit 443 may be connected between a third input signal node 423 and the upper RTSV 132_5, and a fourth switch circuit 444 may be connected between a fourth input signal node 424 and the upper RTSV 132_5. The first to fourth switch circuits 441, 442, 443, and 444 may be respectively referred to as first to fourth input switch circuits 441, 442, 443, and 444.

In the first die 121a, the output signal nodes (that is, 411, 412, 413, and 414) may be respectively connected to the lower NTSVs 131_1, 131_2, 131_3, and 131_4. A first output signal node 411 may be connected to a first lower NTSV 131_1, a second output signal node 412 may be connected to a second lower NTSV 131_2, a third output signal node 413 may be connected to a third lower NTSV 131_3, and a fourth output signal node 414 may be connected to a fourth lower NTSV 131_4. The output switching circuit 430 may include switch circuits (that is, 431, 432, 433, and 434) connected between the lower RTSV 131_5 and each of the output signal nodes (that is, 411, 412, 413, and 414). A first switch circuit 431 may be connected between the lower RTSV 131_5 and a first output signal node 411, a second switch circuit 432 may be connected between the lower RTSV 131_5 and a second output signal node 412, a third switch circuit 433 may be connected between the lower RTSV 131_5 and a third output signal node 413, and a fourth switch circuit 434 may be connected between the lower RTSV 131_5 and a fourth output signal node 414. The first to fourth switch circuits 431, 432, 433, and 434 may be respectively referred to as first to fourth output switch circuits 431, 432, 433, and 434.

Each of the switch circuits (that is, 441 to 444 and 431 to 434) that are included in the input switching circuit 440 and the output switching circuit 430 may include a low-latency switch circuit shown in FIG. 5. Referring to FIG. 5, the first input switch circuit 441, among the switch circuits (that is, 441 to 444 and 431 to 434) of the repair circuit 450, is representatively illustrated. The first input switch circuit 441 may include first and second PMOS transistors 521 and 522 and first and second NMOS transistors 523 and 524, which are connected to each other in parallel, between the upper RTSV 132_5 and both of an inverter 510 and the first input signal node 421. The inverter 510 may receive a first control signal CTRL1 as an input and may output an inverted first control signal/CTRL1. The first control signal CTRL1 may be connected to gates of the first and second PMOS transistors 521 and 522, and the inverted first control signal/CTRL1 may be connected to gates of the first and second NMOS transistors 523 and 524. When the first control signal CTRL1 is activated to a logic low level, the first and second PMOS transistors 521 and 522 and the first and second NMOS transistors 523 and 524 are turned on, and the first input signal node 421 may be connected to the upper RTSV 132_5. Therefore, a signal IS1 that is input to the first input signal node 421 may be provided as an output signal OS1 of the first input switch circuit 441 to the upper RTSV 132_5. When the first control signal CTRL1 is deactivated to a logic high level, the first and second PMOS transistors 521 and 522 and the first and second NMOS transistors 523 and 524 are turned off. This means that the first input signal node 421 is connected to the first upper NTSV 132_1.

In one or more embodiments, the repair circuit 450 may generate a control signal provided to each of the switch circuits (that is, 441 to 444 and 431 to 434). Each of the switch circuits (that is, 441 to 444 and 431 to 434) may include an inverter that receives a control signal corresponding thereto as an input and outputs an inverted control signal. Each of the switch circuits (that is, 441 to 444 and 431 to 434) may include i PMOS transistors (where i is a natural number of 2 or more) and i NMOS transistors, which are connected to each other in parallel, between an input node (for example, 421) and an output node (for example, 132_5). The i PMOS transistors may transfer a signal of the input node to the output node, in response to the activation of the corresponding control signal, and the i NMOS transistors may also transfer the signal of the input node to the output node, in response to the activation of the corresponding control signal.

In one or more embodiments, the repair circuit 450 may detect whether a defect occurs in the TSVs (that is, 131_1, 131_2, 131_3, 131_4, and 131_5) of the first die 121a or the TSVs (that is, 132_1, 132_2, 132_3, 132_4, and 132_5) of the second die 122a. When a failed NTSV is detected from among the NTSVs (that is, 131_1, 131_2, 131_3, 131_4, 132_1, 132_2, 132_3, and 132_4), the repair circuit 450 may generate a control signal CTRL for replacing the failed NTSV by an RTSV (that is, 131_5 and 132_5).

For example, when the first upper NTSV 132_1 of the second die 122a is detected to have failed, the repair circuit 450 may activate the first control signal CTRL1 and may enable the first input switch circuit 441. When the first control signal CTRL1 is activated to a logic low level, the first upper NTSV 132_1 that failed may be repaired by the upper RTSV 132_5, and the first input signal node 421 may be connected to the upper RTSV 132_5. The upper RTSV 132_5 of the second die 122a is electrically connected to the lower RTSV 131_5 of the first die 121a. When the first upper NTSV 132_1 of the second die 122a failed, the repair circuit 450 determines that the first lower NTSV 131_1 of the first die 121a also failed, the first lower NTSV 131_1 being electrically connected to the first upper NTSV 132_1. Therefore, the repair circuit 450 may also provide the activated first control signal CTRL1 to the first output switch circuit 431 connected to the first lower NTSV 131_1.

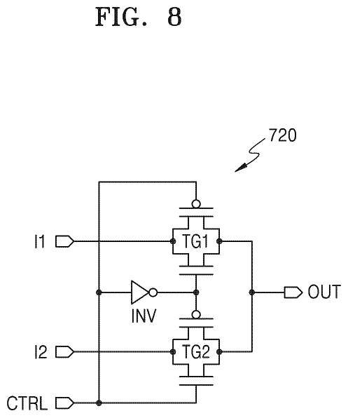

When the first input switch circuit 441 is enabled, the signal IS1 of the first input signal node 421 may be transferred to the upper RTSV 132_5 through four transistors including the first and second PMOS transistors 521 and 522 and the first and second NMOS transistors 523 and 524. This means that the first input switch circuit 441 is a low-latency switch circuit having a double-driving capability and having low latency, as compared with a 2:1 multiplexer 720 that is to be described with reference to FIG. 8. The strong driving capability of the first input switch circuit 441 means that signal transfer from the first input signal node 421 to the upper RTSV 132_5 may be quickly performed even when the failed first upper NTSV 132_1 is connected to the first input signal node 421.

In one or more embodiments, when the repair circuit 450 detects that the second upper NTSV 132_2 failed, the repair circuit 450 may activate a second control signal, may enable the second input switch circuit 442, and may cause a signal of the second input signal node 422 to be transferred to the upper RTSV 132_5 and the lower RTSV 131_5. When the repair circuit 450 detects that the third upper NTSV 132_3 failed, the repair circuit 450 may activate a third control signal, may enable the third input switch circuit 443, and may cause a signal of the third input signal node 423 to be transferred to the upper RTSV 132_5 and the lower RTSV 131_5. When the repair circuit 450 detects that the fourth upper NTSV 132_4 failed, the repair circuit 450 may activate a fourth control signal, may enable the fourth input switch circuit 444, and may cause a signal of the fourth input signal node 424 to be transferred to the upper RTSV 132_5 and the lower RTSV 131_5.

The first to fourth output switch circuits 431, 432, 433, and 434 of the output switching circuit 430 may each be configured identical to the first input switch circuit 441 of FIG. 5. However, the first input signal node 421 of FIG. 3 may correspond to the lower RTSV 131_5 of the first die 121a, and the upper RTSV 132_5 of FIG. 3 may correspond to each of the output signal nodes (that is, 411, 412, 413, and 414) of the first die 121a.

In one or more embodiments, when the repair circuit 450 detects that the first lower NTSV 131_1 failed, the repair circuit 450 may activate a first control signal, may enable the first output switch circuit 431, and may cause the signal of the first input signal node 421, which is transferred to the lower RTSV 131_5 through the upper RTSV 132_5, to be transferred to the first output signal node 411. When the repair circuit 450 detects that the second lower NTSV 131_2 failed, the repair circuit 450 may activate a second control signal, may enable the second output switch circuit 432, and may cause the signal of the second input signal node 422, which is transferred to the lower RTSV 131_5 through the upper RTSV 132_5, to be transferred to the second output signal node 412. When the repair circuit 450 detects that the third lower NTSV 131_3 failed, the repair circuit 450 may activate a third control signal, may enable the third output switch circuit 433, and may cause the signal of the third input signal node 423, which is transferred to the lower RTSV 131_5 through the upper RTSV 132_5, to be transferred to the third output signal node 413. When the repair circuit 450 detects that the fourth lower NTSV 131_4 failed, the repair circuit 450 may activate a fourth control signal, may enable the fourth output switch circuit 434, and may cause the signal of the fourth input signal node 424, which is transferred to the lower RTSV 131_5 through the upper RTSV 132_5, to be transferred to the fourth output signal node 414.

FIG. 6 illustrates an example in which a defect is detected in the second lower NTSV 131_2 of the first die 121a and/or the second upper NTSV 132_2 of the second die 122a. For the simplicity of a circuit connection relationship, disabled components are shown to be pale in that no connection is made to the disabled components.

Referring to FIG. 6, the repair circuit 450 may detect defects of the second lower NTSV 131_2 and/or the second upper NTSV 132_2 of the second die 122a, may activate a second control signal, may enable the second input switch circuit 442 of the input switching circuit 440, and may enable the second output switch circuit 432 of the output switching circuit 430. The first, third, and fourth input switch circuits 441, 443, and 444 of the input switching circuit 440 and the first, third, and fourth output switch circuits 431, 433, and 434 of the output switching circuit 430 are disabled.

The first input signal node 421 of the second die 122a may be connected to the first output signal node 411 of the first die 121a through the first upper NTSV 132_1 and the first lower NTSV 131_1. The second input signal node 422 of the second die 122a may be connected to the second output signal node 412 of the first die 121a through the second input switch circuit 442, the upper RTSV 132_5, the lower RTSV 131_5, and the second output switch circuit 432. The third input signal node 423 of the second die 122a may be connected to the third output signal node 413 of the first die 121a through the third upper NTSV 132_3 and the third lower NTSV 131_3. The fourth input signal node 424 of the second die 122a may be connected to the fourth output signal node 414 of the first die 121a through the fourth upper NTSV 132_4 and the fourth lower NTSV 131_4.

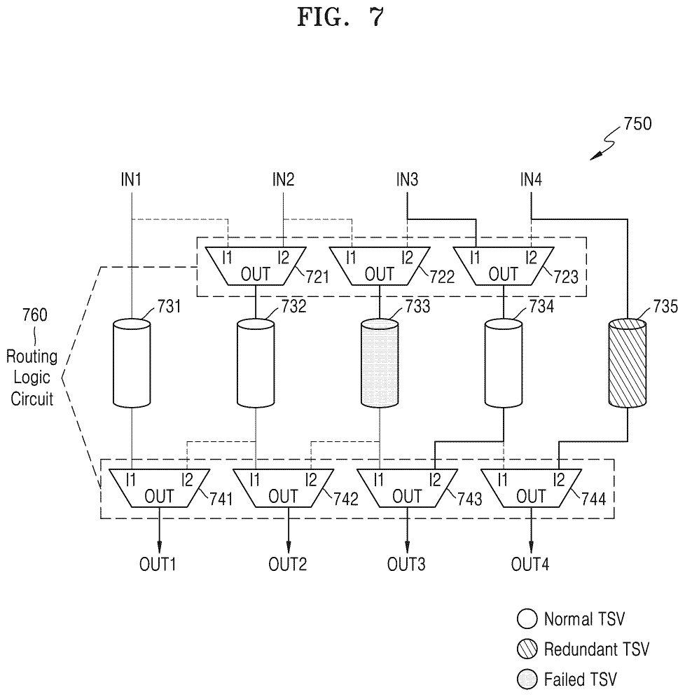

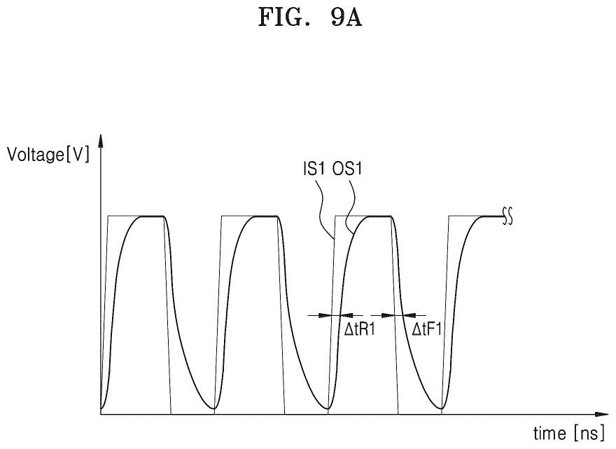

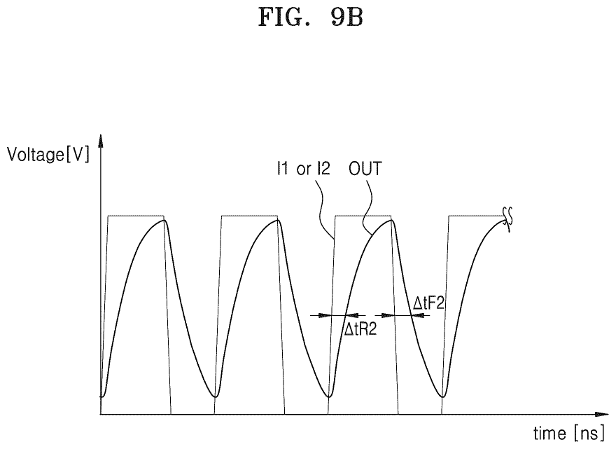

FIGS. 7 and 8 are diagrams illustrating a comparative example related to the repair circuit 450. FIGS. 9A and 9B respectively illustrate operation timing diagrams of the low-latency switch circuit 441 of FIG. 5 and the 2:1 multiplexer circuit 720 of FIG. 8.

Referring to FIG. 7, like the repair circuit 450 of FIG. 4, a repair circuit 750 may repair one failed NTSV (for example, 733) from among four NTSVs (that is, 731, 732, 733, and 734). The repair circuit 750 may include a routing logic circuit 760 for repairing the failed NTSV (that is, 733) by using an RTSV (that is, 735). The routing logic circuit 760 may include a plurality of multiplexer circuits (that is, 721, 722, 723, 741, 742, 743, and 744) and may have a signal shifting structure.

The multiplexer circuits (that is, 721, 722, 723, 741, 742, 743, and 744) may each be implemented by a 2:1 multiplexer circuit 720, as shown in FIG. 8. Referring to FIG. 8, the 2:1 multiplexer circuit 720 may include a first transmission gate TG1 connected between a first input terminal I1 and an output terminal OUT, a second transmission gate TG2 connected between a second input terminal I2 and the output terminal OUT, and an inverter INV to which a control signal CTRL is input. When the control signal CTRL is at a logic low level, a signal of the first input terminal I1 may be transferred to the output terminal OUT through the first transmission gate TG1, and when the control signal CTRL is at a logic high level, a signal of the second input terminal I2 may be transferred to the output terminal OUT through the second transmission gate TG2.

In FIG. 7, a first input signal IN1 may be provided to a first NTSV 731. In addition, the first input signal IN1 may be provided to the first input terminal I1 of a first input multiplexer circuit 721. A second input signal IN2 may be provided to the second input terminal 12 of the first input multiplexer circuit 721 and the first input terminal I1 of a second input multiplexer circuit 722. The first input signal IN1 may be input to the first input terminal I1 of the first input multiplexer circuit 721, and the second input signal IN2 may be input to the second input terminal I2 of the first input multiplexer circuit 721. The routing logic circuit 760 may cause the second input signal IN2 of the second input terminal I2 of the first input multiplexer circuit 721 to be transferred to the output terminal OUT, thereby providing the second input signal IN2 to a second NTSV 732.

A third input signal IN3 may be provided to the second input terminal I2 of the second input multiplexer circuit 722 and the first input terminal I1 of a third input multiplexer circuit 723. The second input signal IN2 may be input to the first input terminal I1 of the second input multiplexer circuit 722, and the third input signal IN3 may be input to the second input terminal I2 of the second input multiplexer circuit 722. As a third NTSV 733 is detected to have failed, the routing logic circuit 760 may cause the third input signal IN3 of the second input terminal I2 of the second input multiplexer circuit 722 not to be provided to the third NTSV 733 that failed. That is, the routing logic circuit 760 may cause the second input signal IN2 of the first input terminal I1 of the second input multiplexer circuit 722 to be transferred to the output terminal OUT, whereby the second input signal IN2 is provided to the second NTSV 732 that failed, and the third input signal IN3 is not provided to the third NTSV 733 that failed.

A fourth input signal IN4 may be provided to the second input terminal I2 of the third input multiplexer circuit 723 and the RTSV 735. The third input signal IN3 may be input to the first input terminal I1 of the third input multiplexer circuit 723, and the fourth input signal IN4 may be input to the second input terminal I2 of the third input multiplexer circuit 723. The routing logic circuit 760 may cause the third input signal IN3 of the first input terminal I1 of the third input multiplexer circuit 723 to be transferred to the output terminal OUT, thereby providing the third input signal IN3 to a fourth NTSV 734. The fourth input signal IN4 may be provided to the RTSV 735.

The first input signal IN1 transferred through the first NTSV 731 may be input to the first input terminal I1 of a first output multiplexer circuit 741, and the second input signal IN2 transferred through the second NTSV 732 may be input to a second input terminal I2 of the first output multiplexer circuit 741. The routing logic circuit 760 may cause the first input signal IN1 of the first input terminal I1 of the first output multiplexer circuit 741 to be transferred to the output terminal OUT, thereby outputting the first input signal IN1 as a first output signal OUT1. The second input signal IN2 transferred through the second NTSV 732 may be input to a first input terminal I1 of a second output multiplexer circuit 742, and the second input signal IN2 transferred through the third NTSV 733 that failed may be input to a second input terminal I2 of the second output multiplexer circuit 742. The routing logic circuit 760 may cause the second input signal IN2 of the first input terminal I1 of the second output multiplexer circuit 742 to be transferred to the output terminal OUT, thereby outputting the second input signal IN2 as a second output signal OUT2.

The second input signal IN2 transferred through the third NTSV 733 that failed may be input to a first input terminal I1 of a third output multiplexer circuit 743, and the third input signal IN3 transferred through a fourth NTSV 734 may be input to a second input terminal 12 of the third output multiplexer circuit 743. The routing logic circuit 760 may cause the third input signal IN3 of the second input terminal I2 of the third output multiplexer circuit 743 to be transferred to the output terminal OUT, thereby outputting the third input signal IN3 as a third output signal OUT3. The third input signal IN3 transferred through the fourth NTSV 734 may be input to a first input terminal I1 of a fourth output multiplexer circuit 744, and the fourth input signal IN4 transferred through the RTSV 735 may be input to a second input terminal I2 of the fourth output multiplexer circuit 744. The routing logic circuit 760 may cause the fourth input signal IN4 of the second input terminal I2 of the fourth output multiplexer circuit 744 to be transferred to the output terminal OUT, thereby outputting the fourth input signal IN4 as a fourth output signal OUT4.

As described above, according to the signal shifting operation performed by the routing logic circuit 760 of FIG. 7, an operation of causing a signal needing to pass through a failed NTSV to take a bypass to an adjacent NTSV may be sequentially performed such that the signal is shifted finally up to the RTSV. This may generate an issue of significant signal latency. As another comparative example, to increase a repair rate, a ring-based repair circuit, in which NTSVs are concentrically arranged and an RTSV is arranged outside the NTSVs, has been proposed, and thus, when there are a lot of failed NTSVs in a specific NTSV group, the failed NTSVs may be repaired by using an RTSV of an adjacent next RTSV group. This may also generate an issue of signal latency due to complicated bypass paths. To solve such signal latency issues, a low-latency switch circuit (see FIG. 5) having low latency is provided.

FIG. 9A illustrates an operation timing diagram of the low-latency switch circuit 441 of FIG. 5, and FIG. 9B illustrates an operation timing diagram of the 2:1 multiplexer circuit 720 of FIG. 8. In FIG. 9A, the delay time of the low-latency switch circuit 441, from the input signal IS1 to the output signal OS1, may be represented by time ΔtR1 and time ΔtF1. In FIG. 9B, the delay time of the 2:1 multiplexer circuit 720, from the input signal I1 or I2 to the output signal OUT, may be represented by time ΔtR2 and time ΔtF2. The times ΔtR1 and ΔtR2 refer to rise-signal delay times, and the times ΔtF1 and ΔtF2 refer to fall-signal delay times.

It may be seen that the rise-signal delay time ΔtR1 of the low-latency switch circuit 441 is shorter than the rise-signal delay time ΔtR2 of the 2:1 multiplexer circuit 720. It may be seen that the fall-signal delay time ΔtF1 of the low-latency switch circuit 441 is also shorter than the fall-signal delay time ΔtF2 of the 2:1 multiplexer circuit 720. This may be understood as resulting from the difference in delay time due to the difference in driving capability, because the low-latency switch circuit 441 causes the input signal IS1 to be output as the output signal OS1 by driving four transistors (that is, 521, 522, 523, and 524) and the 2:1 multiplexer circuit 720 causes the input signal I1 or I2 to be output as the output signal OUT by driving two transistors constituting each of the first transmission gate TG1 and the second transmission gate TG2. That is, the low-latency switch circuit 441 has a double-driving capability and lower latency, as compared with the 2:1 multiplexer circuit 720. Therefore, a repair operation may be quickly performed on a failed TSV by using the low-latency switch circuit 441.

FIGS. 10 and 11 are diagrams illustrating a repair circuit for repairing a failed TSV, according to one or more embodiments. In a 3D IC 100b of FIG. 10, a first die 121b and a second die 122b each include eight NTSVs and one RTSV. Except that there are a larger number of NTSVs, the embodiment of FIG. 10 may be substantially identical to the embodiment of FIG. 4. Hereinafter, repeated descriptions given with reference to FIG. 4 are omitted.

Referring to FIGS. 1 and 10, the first die 121b may include a plurality of NTSVs (that is, 131_1, 131_2, 131_3, 131_4, 131_6, 131_7, 131_8, and 131_9) and one RTSV 131_5. The second die 122b may include a plurality of NTSVs (that is, 132_1, 132_2, 132_3, 132_4, 132_6, 132_7, 132_8, 132_9. The TSVs (that is, 132_1, 132_2, 132_3, 132_4, 132_5, 132_6, 132_7, 132_8, and 132_9) of the second die 122b may be arranged opposite to the TSVs (that is, 131_1, 131_2, 131_3, 131_4, 131_5, 131_6, 131_7, 131_8, and 131_9) of the first die 121b.

The first die 121b and the second die 122b may include a repair circuit 1050 for repairing a failed TSV. The repair circuit 1050 may include a first switching circuit 1040 and a second switching circuit 1030. Here, the first switching circuit 1040 may be included in the second die 122b, and the second switching circuit 1030 may be include in the first die 121b. The first switching circuit 1040 may be connected between the upper RTSV 132_5 and input signal nodes (that is, 421, 422, 423, 424, 426, 427, 428, and 429) of the second die 122b. The second switching circuit 1030 may be connected between the lower RTSV 131_5 and output signal nodes (that is, 411, 412, 413, 414, 416, 417, 418, and 419) of the first die 121b.

In the second die 122b, the input signal nodes (that is, 421, 422, 423, 424, 426, 427, 428, and 429) may be respectively connected to the upper NTSVs (that is, 132_1, 132_2, 132_3, 132_4, 132_6, 132_7, 132_8, and 132_9). A first input signal node 421 may be connected to a first upper NTSV 132_1, a second input signal node 422 may be connected to a second upper NTSV 132_2, a third input signal node 423 may be connected to a third upper NTSV 132_3, a fourth input signal node 424 may be connected to a fourth upper NTSV 132_4, a fifth input signal node 426 may be connected to a fifth upper NTSV 132_6, a sixth input signal node 427 may be connected to a sixth upper NTSV 132_7, a seventh input signal node 428 may be connected to a seventh upper NTSV 132_8, and an eighth input signal node 429 may be connected to an eighth upper NTSV 132_9.

The input switching circuit 1040 may include input switch circuits (that is, 441, 442, 443, 444, 446, 447, 448, and 449) connected between the upper RTSV 132_5 and each of the input signal nodes (that is, 421, 422, 423, 424, 426, 427, 428, and 429). The input switch circuits (that is, 441, 442, 443, 444, 446, 447, 448, and 449) may each be implemented by the low-latency switch circuit 441 described with reference to FIG. 5. A first input switch circuit 441 may be connected between the first input signal node 421 and the upper RTSV 132_5, a second input switch circuit 442 may be connected between the second input signal node 422 and the upper RTSV 132_5, a third input switch circuit 443 may be connected between the third input signal node 423 and the upper RTSV 132_5, a fourth input switch circuit 444 may be connected between the fourth input signal node 424 and the upper RTSV 132_5, a fifth input switch circuit 446 may be connected between the fifth input signal node 426 and the upper RTSV 132_5, a sixth input switch circuit 447 may be connected between the sixth input signal node 427 and the upper RTSV 132_5, a seventh input switch circuit 448 may be connected between the seventh input signal node 428 and the upper RTSV 132_5, and an eighth input switch circuit 449 may be connected between the eighth input signal node 429 and the upper RTSV 132_5.

In the first die 121b, the output signal nodes (that is, 411, 412, 413, 414, 416, 417, 418, and 419) may be respectively connected to the lower NTSVs (that is, 131_1, 131_2, 131_3, 131_4, 131_6, 131_7, 131_8, and 131_9). A first output signal node 411 may be connected to a first lower NTSV 131_1, a second output signal node 412 may be connected to a second lower NTSV 131_2, a third output signal node 413 may be connected to a third lower NTSV 131_3, a fourth output signal node 414 may be connected to a fourth lower NTSV 131_4, a fifth output signal node 416 may be connected to a fifth lower NTSV 131_6, a sixth output signal node 417 may be connected to a sixth lower NTSV 131_7, a seventh output signal node 418 may be connected to a seventh lower NTSV 131_8, and an eighth output signal node 419 may be connected to an eighth lower NTSV 131_9.

The output switching circuit 1030 may include output switch circuits (that is, 431, 432, 433, 434, 436, 437, 438, and 439) connected between the lower RTSV 131_5 and each of the output signal nodes (that is, 411, 412, 413, 414, 416, 417, 418, and 419). The output signal nodes (that is, 411, 412, 413, 414, 416, 417, 418, and 419) may each be implemented by the low-latency switch circuit 441 described with reference to FIG. 5. A first output switch circuit 431 may be connected between the lower RTSV 131_5 and the first output signal node 411, a second output switch circuit 432 may be connected between the lower RTSV 131_5 and a second output signal node 412, a third output switch circuit 433 may be connected between the lower RTSV 131_5 and a third output signal node 413, a fourth output switch circuit 434 may be connected between the lower RTSV 131_5 and a fourth output signal node 414, a fifth output switch circuit 436 may be connected between the lower RTSV 131_5 and a fifth output signal node 416, a sixth output switch circuit 437 may be connected between the lower RTSV 131_5 and a sixth output signal node 417, a seventh output switch circuit 438 may be connected between the lower RTSV 131_5 and a seventh output signal node 418, and an eighth output switch circuit 439 may be connected between the lower RTSV 131_5 and an eighth output signal node 419.

The repair circuit 1050 may detect whether a defect occurs in the NTSVs (that is, 131_1, 131_2, 131_3, 131_4, 131_6, 131_7, 131_8, and 131_9) of the first die 121b or the NTSVs (that is, 132_1, 132_2, 132_3, 132_4, 132_6, 132_7, 132_8, and 132_9) of the second die 122b. As shown in FIG. 11, when it is detected that the first upper NTSV 132_1 of the second die 122b failed, the repair circuit 1050 may enable the first input switch circuit 441 and the first output switch circuit 431. The second to eighth input switch circuits 442, 443, 444, 446, 447, 448, and 449 of the input switching circuit 1040 and the second to eighth output switch circuits 432, 433, 434, 436, 437, 438, and 439 of the output switching circuit 1030 are disabled.

Referring to FIG. 11, when the first input switch circuit 441 and the first output switch circuit 431 are enabled, the first input signal node 421 of the second die 122a may be connected to the first output signal node 411 of the first die 121a through the first input switch circuit 441, the upper RTSV 132_5, the lower RTSV 131_5, and the first output switch circuit 431. The second input signal node 422 of the second die 122b may be connected to the second output signal node 412 of the first die 121b through the second upper NTSV 132_2 and the second lower NTSV 131_2. The third input signal node 423 of the second die 122b may be connected to the third output signal node 413 of the first die 121b through the third upper NTSV 132_3 and the third lower NTSV 131_3. The fourth input signal node 424 of the second die 122b may be connected to the fourth output signal node 414 of the first die 121b through the fourth upper NTSV 132_4 and the fourth lower NTSV 131_4, and the fifth input signal node 426 of the second die 122b may be connected to the fifth output signal node 416 of the first die 121b through the fifth upper NTSV 132_6 and the fifth lower NTSV 131_6. The sixth input signal node 427 of the second die 122b may be connected to the sixth output signal node 417 of the first die 121b through the sixth upper NTSV 132_7 and the sixth lower NTSV 131_7. The seventh input signal node 428 of the second die 122b may be connected to the seventh output signal node 418 of the first die 121b through the seventh upper NTSV 132_8 and the seventh lower NTSV 131_8. The eighth input signal node 429 of the second die 122b may be connected to the eighth output signal node 419 of the first die 121b through the eighth upper NTSV 132_9 and the eighth lower NTSV 131_9.

The repair circuit 1050 may quickly perform a repair operation in which the failed first upper NTSV 132_1 and the first lower NTSV 131_1 connected to the failed first upper NTSV 132_1 are respectively repaired with the upper RTSV 132_5 and the lower RTSV 131_5 by using the first input switch circuit 441 and the first output switch circuit 431 each implemented by the low-latency switch circuit 441.

FIGS. 12 and 13 are diagrams illustrating a repair circuit for repairing a failed TSV, according to one or more embodiments. Hereinafter, repeated descriptions given with reference to FIG. 4 are omitted.

Referring to FIGS. 1 and 12, in a 3D IC 100c, a first die 121c and a second die 122c each include four NTSVs and two RTSVs. The first die 121c may include four NTSVs (that is, 1231_1, 1231_2, 1231_3, and 1231_4) and two RTSVs (that is, 1231_5 and 1231_6). The second die 122c may include four NTSVs (that is, 1232_1, 1232_2, 1232_3, and 1232_4) and two RTSVs (that is, 1232_5 and 1232_6). The TSVs (that is, 1232_1, 1232_2, 1232_3, 1232_4, 1232_5, and 1232_6) of the second die 122c may be respectively arranged opposite to the TSVs (that is, 1231_1, 1231_2, 1231_3, 1231_4, 1231_5, and 1231_6) of the first die 121c.

The first die 121c and the second die 122c may include a repair circuit 1250 for repairing a failed TSV. The repair circuit 1250 may include a first switching circuit 1240 and a second switching circuit 1230. Here, the first switching circuit 1240 may be included in the second die 122c, and the second switching circuit 1230 may be included in the first die 121c. The first switching circuit 1240 may be connected between the upper RTSVs (that is, 1232_5 and 1232_6) and input signal nodes (that is, 1221, 1222, 1223, and 1224) of the second die 122c. The second switching circuit 1230 may be connected between the lower RTSVs (that is, 1231_5 and 1231_6) and output signal nodes (that is, 1211, 1212, 1213, and 1214) of the first die 121c.

In the second die 122c, the input signal nodes (that is, 1221, 1222, 1223, and 1224) may be respectively connected to the upper NTSVs (that is, 1232_1, 1232_2, 1232_3, and 1232_4). A first input signal node 1221 may be connected to a first upper NTSV 1232_1, a second input signal node 1222 may be connected to a second upper NTSV 1232_2, a third input signal node 1223 may be connected to a third upper NTSV 1232_3, and a fourth input signal node 1224 may be connected to a fourth upper NTSV 1232_4.

The input switching circuit 1240 may include input switch circuits (that is, 1241, 1242, 1243, 1244, 1245, 1226, 1247, and 1248) connected between each of the input signal nodes (that is, 1221, 1222, 1223, and 1224) and the upper RTSVs (that is, 1232_5 and 1232_6). The input switch circuits (that is, 1241, 1242, 1243, 1244, 1245, 1226, 1247, and 1248) may each be implemented by the low-latency switch 441 described with reference to FIG. 5. A first input switch circuit 1241 may be connected between a first input signal node 1221 and a first upper RTSV 1232_5, a second input switch circuit 1242 may be connected between a second input signal node 1222 and the first upper RTSV 1232_5, a third input switch circuit 1243 may be connected between a third input signal node 1223 and the first upper RTSV 1232_5, a fourth input switch circuit 1244 may be connected between a fourth input signal node 1224 and the first upper RTSV 1232_5, a fifth input switch circuit 1245 may be connected between the first input signal node 1221 and a second upper RTSV 1232_6, a sixth input switch circuit 1246 may be connected between the second input signal node 1222 and the second upper RTSV 1232_6, a seventh input switch circuit 1247 may be connected between the third input signal node 1223 and the second upper RTSV 1232_6, and an eighth input switch circuit 1248 may be connected between the fourth input signal node 1224 and the second upper RTSV 1232_6.

In the first die 121c, output signal nodes (that is, 1211, 1212, 1213, and 1214) may be respectively connected to lower NTSVs (that is, 1231_1, 1231_2, 1231_3, and 1231_4). A first output signal node 1211 may be connected to a first lower NTSV 1231_1, a second output signal node 1212 may be connected to a second lower NTSV 1231_2, a third output signal node 1213 may be connected to a third lower NTSV 1231_3, and a fourth output signal node 1214 may be connected to a fourth lower NTSV 1231_4.

The output switching circuit 1230 may include output switch circuits (that is, 1231, 1232, 1233, 1234, 1235, 1236, 1237, and 1238) connected between the lower RTSVs (that is, 1231_5 and 1231_6) and each of the output signal nodes (that is, 1211, 1212, 1213, and 1214). The output switch circuits (that is, 1231, 1232, 1233, 1234, 1235, 1236, 1237, and 1238) may each be implemented by the low-latency switch 441 described with reference to FIG. 5. A first output switch circuit 1231 may be connected between a first lower RTSV 1231_5 and a first output signal node 1211, a second output switch circuit 1232 may be connected between the first lower RTSV 1231_5 and a second output signal node 1212, a third output switch circuit 1233 may be connected between the first lower RTSV 1231_5 and a third output signal node 1213, a fourth output switch circuit 1234 may be connected between the first lower RTSV 1231_5 and a fourth output signal node 1214, a fifth output switch circuit 1235 may be connected between a second lower RTSV 1231_6 and the first output signal node 1211, a sixth output switch circuit 1236 may be connected between the second lower RTSV 1231_6 and the second output signal node 1212, a seventh output switch circuit 1237 may be connected between the second lower RTSV 1231_6 and the third output signal node 1213, and an eighth output switch circuit 1238 may be connected between the second lower RTSV 1231_6 and the fourth output signal node 1214.

The repair circuit 1250 may detect whether defects occur in the NTSVs (that is, 1231_1, 1231_2, 1231_3, and 1231_4) of the first die 121c or the NTSVs (that is, 1232_1, 1232_2, 1232_3, and 1232_4) of the second die 122c. The repair circuit 1250 may detect that the second upper NTSV 1232_2 and the fourth upper NTSV 1232_4 of the second die 122c failed, that is, may detect two failed NTSVs, as shown in FIG. 13. The repair circuit 1250 may enable the fourth input switch circuit 1244 and the fourth output switch circuit 1234 and may enable the sixth input switch circuit 1246 and the sixth output switch circuit 1236. The first, second, third, fifth, seventh, and eighth input switch circuits 1241, 1242, 1243, 1245, 1247, and 1248 of the input switching circuit 1240 and the first, second, third, fifth, seventh, and eighth output switch circuits 1231, 1232, 1233, 1235, 1237, and 1238 of the output switching circuit 1230 are disabled.

Referring to FIG. 13, when the fourth input switch circuit 1244 and the fourth output switch circuit 1234 are enabled, the fourth input signal node 1224 of the second die 122c may be connected to the fourth output signal node 1214 of the first die 121c through the fourth input switch circuit 1244, the first upper RTSV 1232_5, the first lower RTSV 1231_5, and the fourth output switch circuit 1234. When the sixth input switch circuit 1246 and the sixth output switch circuit 1236 are enabled, the second input signal node 1222 of the second die 122c may be connected to the second output signal node 1212 of the first die 121c through the sixth input switch circuit 1246, the second upper RTSV 1232_6, the second lower RTSV 1231_6, and the sixth output switch circuit 1236. The first input signal node 1221 of the second die 122c may be connected to the first output signal node 1211 of the first die 121c through the first upper NTSV 1232_1 and the first lower NTSV 1231_1. The third input signal node 1223 of the second die 122c may be connected to the third output signal node 1213 of the first die 121c through the third upper NTSV 1232_3 and the third lower NTSV 1231_3.

The repair circuit 1250 may quickly perform a repair operation in which the failed second and fourth upper NTSVs 1232_2 and 1232_4 and the second and fourth lower NTSVs 1231_2 and 1231_4 respectively connected to the failed second and fourth upper NTSVs 1232_2 and 1232_4 are repaired with the first and second upper RTSVs 1232_5 and 1232_6 and the first and second lower RTSVs 1231_5 and 1231_6 by using the fourth input and output switch circuits 1244 and 1234 and the sixth input and output switch circuits 1246 and 1236, which are each implemented by the low-latency switch circuit 441.

FIGS. 14A and 14B are diagrams each illustrating a TSV repair unit, according to one or more embodiments.

Referring to FIG. 14A, it is illustrated that a TSV repair unit 1410 includes a set of 32 NTSVs and 4 RTSVs. The low-latency switch circuit 441 (see FIG. 5), which is connected to each of the 32 NTSVs, may be connected to each of the 4 RTSVs. This means that, when 4 NTSVs from among the 32 NTSVs failed, the 4 failed NTSVs may be repaired with the 4 RTSVs.

Referring to FIG. 14B, it is illustrated that a TSV repair unit 1420 includes a set of 30 NTSVs and 6 RTSVs. The low-latency switch circuit 441, which is connected to each of the 30 NTSVs, may be connected to each of the 6 RTSVs. This means that, when 6 NTSVs from among the 30 NTSVs failed, the 6 failed NTSVs may be repaired with the 6 RTSVs.

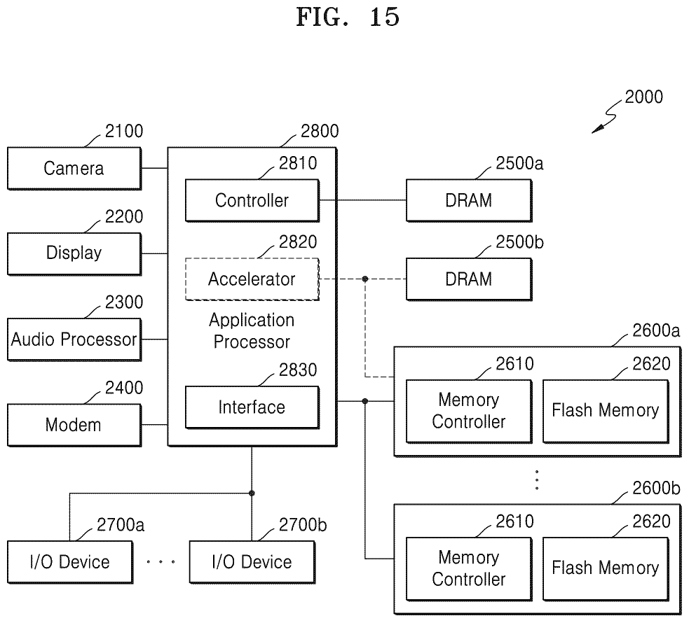

FIG. 15 is a block diagram of a system 2000, for illustrating an electronic apparatus including a semiconductor integrated circuit, according to one or more embodiments.

Referring to FIG. 15, the system 2000 may include a camera 2100, a display 2200, an audio processor 2300, a modem 2400, DRAMs 2500a and 2500b, flash memories 2600a and 2600b, input/output (I/O) devices 2700a and 2700b, and an AP 2800. The system 2000 may be implemented by a laptop computer, a mobile phone, a smartphone, a tablet personal computer (PC), a wearable device, a healthcare device, or an Internet-of-Things (IoT) device. In addition, the system 2000 may be implemented by a server or a PC.

The camera 2100 may capture a still image or a video according to control by a user and may store captured image/video data or transmit captured image/video data to the display 2200. The audio processor 2300 may process audio data that is included in content of the flash memories 2600a and 2600b or a network. The modem 2400 may modulate and transmit a signal, for wired/wireless transmission and reception and may perform demodulation at a reception side thereof for the restoration into an original signal. The I/O devices 2700a and 2700b may include devices providing digital input and/or output functions, such as Universal Serial Bus (USB), a storage, a digital camera, a Secure Digital (SD) card, a digital versatile disc (DVD), a network adapter, and a touchscreen.

The AP 2800 may control all operations of the system 2000. The AP 2800 may include a controller block 2810, an accelerator block or accelerator chip 2820, and an interface block 2830. The AP 2800 may control the display 2200 such that a portion of content stored in the flash memories 2600a and 2600b is displayed on the display 2200. When a user input is received through the I/O devices 2700a and 2700b, the AP 2800 may perform a control operation corresponding to the user input. The AP 2800 may include an accelerator block, which is a dedicated circuit for an artificial intelligence (AI) data operation, or an accelerator chip 2820 may be provided separately from the AP 2800. The DRAM 2500b may be additionally mounted on the accelerator block or the accelerator chip 2820. An accelerator is a functional block specialized in performing a specific function of the AP 2800 and may include a GPU that is a functional block specialized in performing graphics data processing, an NPU that is a functional block specialized in performing AI calculation and inference, or a data processing unit (DPU) specialized in performing data transmission. In one or more embodiments, an image captured via the camera 2100 by a user may be signal-processed and stored in the DRAM 2500b, and the accelerator block or accelerator chip 2820 may perform an AI data operation for recognizing data by using the data stored in the DRAM 2500b and a function used for inference.

The system 2000 may include a plurality of DRAMs 2500a and 2500b. The AP 2800 may set a command and a mode register (MRS) based on joint electron device engineering council (JEDEC) standard to control the DRAMs 2500a and 2500b, or may perform communication by setting DRAM interface standard so as to use cyclic redundancy check (CRC)/error correction code (ECC) and a company unique function such as low voltage/high speed/reliability. For example, the AP 2800 may communicate with the DRAM 2500a through an interface, such as LPDDR4 or LPDDR5, conforming to the JEDEC standard specifications, and may communicate with the DRAM 2500b by setting a new DRAM interface protocol to control the DRAM 2500b for accelerators, the DRAM 2500b having a higher bandwidth than the DRAM 2500a.

Although FIG. 15 illustrates only the DRAMs 2500a and 2500b, the disclosure is not limited thereto, and any memory, such as PRAM, SRAM, MRAM, RRAM, FRAM, or Hybrid RAM, may be used as long as the memory satisfies bandwidth, response speed, and voltage conditions for the AP 2800 or the accelerator chip 2820. The DRAMs 2500a and 2500b have relatively smaller latencies and bandwidths than the I/O devices 2700a and 2700b or the flash memories 2600a and 2600b. The DRAMs 2500a and 2500b may be initialized at a time point of Power-On of the system 2000 and may be used as a temporary storage area of an operating system and application data by allowing the operating system and the application data to be loaded into the DRAMs 2500a and 2500b or may be used as an execution space of various pieces of software code.

In the DRAMs 2500a and 2500b, four fundamental arithmetic operations including addition, subtraction, multiplication, and division, vector operations, address operations, or Fast Fourier Transform (FFT) operations may be performed. Also, a function used in inference may be performed in the DRAMs 2500a and 2500b. Here, the inference may be performed in a deep learning algorithm using an artificial neural network. The deep learning algorithm may include a training operation in which a model is trained through various data, and an inference operation in which data is recognized by using the trained model.

The system 2000 may include a plurality of storages or a plurality of flash memories 2600a and 2600b, which have capacities greater than those of the DRAMs 2500a and 2500b. The accelerator block or accelerator chip 2820 may perform a training operation and an AI data operation by using the flash memories 2600a and 2600b. In one or more embodiments, each of the flash memories 2600a and 2600b may include a memory controller 2610 and a flash memory device 2620, and the training operation and an inference AI data operation, which are performed by the AP 2800 and/or the accelerator chip 2820, may be more efficiently performed by using a calculation device arranged in the memory controller 2610. The flash memories 2600a and 2600b may store images captured by the camera 2100 or may store data received via a data network. For example, the flash memories 2600a and 2600b may store augmented reality/virtual reality high-definition (HD) or ultra-high-definition (UHD) content.

The components of the system 2000 may include semiconductor integrated circuits described with reference to FIGS. 1 to 14B. The semiconductor integrated circuit(s) may be implemented by a 3D IC including a plurality of stacked dies, and the dies may be electrically connected to each other through TSVs. The TSVs may include NTSVs for signal transfer and RTSVs for replacing a failed NTSV occurring from among the NTSVs, and may be divided into TSV repair units. Each of the TSV repair units may include n NTSVs (where n is a natural number of 2 or more) and m RTSVs (where m<n) provided for every n NTSVs. The semiconductor integrated circuit(s) may include a repair circuit for detecting defects occurring in the TSVs, and the repair circuit may include first switch circuits, which are connected between a first RTSV and each of first signal nodes respectively connected to first NTSVs of a first die, and second switch circuits, which are connected between a second RTSV and each of second signal nodes respectively connected to second NTSVs of a second die. The repair circuit may detect a first failed NTSV from among the first NTSVs and may activate a first control signal. In addition, the repair circuit may cause a first switch circuit connected to a first signal node connected to the first failed NTSV, among the first switch circuits, to be enabled and the other first switch circuits to be disabled and may cause a second switch circuit connected to a second NTSV connected to the first failed NTSV, among the second switch circuits, to be enabled and the other second switch circuits to be disabled. Each of the first and second switch circuits may be implemented by a low-latency switch. Here, the low-latency switch may include i PMOS transistors (where i is a natural number of 2 or more) and i NMOS transistors, which are connected to each other in parallel, between an input node and an output node, and the PMOS and NMOS transistors may transfer a signal of the input node to the output node in response to the activation of the first control signal. According to the semiconductor integrated circuits performing TSV repair operations by using such low-latency switches, a bypass path to an RTSV may be quickly determined, and a high repair rate may be achieved. Such a semiconductor device may be usefully applied to high-speed communication devices and systems.

While the disclosure has been particularly shown and described with reference to embodiments thereof, it will be understood that various changes in form and details may be made therein without departing from the spirit and scope of the following claims.

1. A semiconductor integrated circuit comprising:
a first die comprising a plurality of first through-silicon vias (TSVs), wherein the plurality of first TSVs are divided into TSV repair units, and the TSV repair units comprise first normal TSVs (NTSVs) for signal transfer and a first redundant TSV (RTSV) for replacing a first failed NTSV from among the first NTSVs;
a second die stacked on the first die and comprising a plurality of second TSVs, wherein the plurality of second TSVs comprise second NTSVs and a second RTSV for the TSV repair units, and the second NTSVs and the second RTSV are respectively arranged opposite to the first NTSVs and the first RTSV and are respectively connected to the first NTSVs and the first RTSV by electrical connection structures; and
a repair circuit configured to detect defects occurring in the first NTSVs and comprising first switch circuits connected between the first RTSV and first signal nodes respectively connected to the first NTSVs,
wherein the repair circuit is further configured to cause a first switch circuit that is connected to a first signal node connected to the first failed NTSV, among the first switch circuits, to be enabled and other of the first switch circuits to be disabled.

2. The semiconductor integrated circuit of claim 1, wherein the repair circuit further comprises second switch circuits connected between the second RTSV and second signal nodes of the second die, the second signal nodes being respectively connected to the second NTSVs.

3. The semiconductor integrated circuit of claim 2, wherein the repair circuit is further configured to cause a second switch circuit that is connected to a second NTSV connected to the first failed NTSV, among the second switch circuits, to be enabled and other of the second switch circuits to be disabled.

4. The semiconductor integrated circuit of claim 2, wherein the repair circuit is further configured to detect a second failed NTSV from among the second NTSVs and cause a second switch circuit that is connected to a second signal node connected to the second failed NTSV, among the second switch circuits, to be enabled and other of the second switch circuits to be disabled.

5. The semiconductor integrated circuit of claim 2,
wherein the repair circuit is further configured to detect the first failed NTSV and activate a first control signal,
wherein the first switch circuit and second switch circuit comprise:
i PMOS transistors connected in parallel between an input node and an output node, the PMOS transistors being configured to transfer a signal of the input node to the output node based on activation of the first control signal; and
i NMOS transistors connected in parallel between the input node and the output node, the NMOS transistors being configured to transfer the signal of the input node to the output node based on the activation of the first control signal, and
wherein i is a natural number of 2 or more.

6. The semiconductor integrated circuit of claim 1, wherein the TSV repair units comprise n NTSVs and m RTSVs, wherein n is a natural number of 2 or more, and m<n.

7. The semiconductor integrated circuit of claim 1, further comprising:
a third die that is stacked on the second die and comprises a plurality of third TSVs,
wherein the plurality of third TSVs of the third die comprise third NTSVs and a third RTSV for the TSV repair units, and
wherein the third NTSVs and the third RTSV are respectively arranged opposite to the second NTSVs and the second RTSV and are respectively connected to the second NTSVs and the second RTSV by electrical connection structures.

8. The semiconductor integrated circuit of claim 7,
wherein the repair circuit further comprises third switch circuits connected between the third RTSV and third signal nodes of the third die, the third signal nodes being respectively connected to the third NTSVs, and
wherein the repair circuit is further configured to detect a third failed NTSV from among the third NTSVs and cause a third switch circuit that is connected to a third signal node connected to the third failed NTSV, among the third NTSVs, to be enabled and other of the third switch circuits to be disabled.

9. A semiconductor integrated circuit comprising:
a first die comprising a plurality of first through-silicon vias (TSVs), wherein the plurality of first TSVs are divided into TSV repair units, and the TSV repair units comprise first normal TSVs (NTSVs) for signal transfer and a first redundant TSV (RTSV) and a second RTSV for respectively replacing a first failed NTSV and a second failed NTSV from among the first NTSVs;
a second die stacked on the first die and comprising a plurality of second TSVs, wherein the plurality of second TSVs comprise second NTSVs and a third RTSV and a fourth RTSV for the TSV repair units, and the second NTSVs, the third RTSV, and the fourth RTSV are respectively arranged opposite to the first NTSVs, the first RTSV, and the second RTSV and are respectively connected to the first NTSVs, the first RTSV, and the second RTSV by electrical connection structures; and
a repair circuit configured to detect defects occurring in the first NTSVs and comprising first switch circuits connected between the first RTSV and first signal nodes respectively connected to the first NTSVs, and second switch circuits connected between the second RTSV and the first signal nodes,
wherein the repair circuit is further configured to cause a first switch circuit that is connected to the first failed NTSV of the first NTSVs, among the first switch circuits, and a second switch circuit that is connected to the second failed NTSV of the first NTSVs, among the second switch circuits, to be enabled and others of the first switch circuits and the second switch circuits to be disabled.

10. The semiconductor integrated circuit of claim 9, wherein the repair circuit further comprises third switch circuits, which are connected between the third RTSV and second signal nodes of the second die, and fourth switch circuits, which are connected between the fourth RTSV and the second signal nodes of the second die, the second signal nodes being respectively connected to the second NTSVs.

11. The semiconductor integrated circuit of claim 10, wherein the repair circuit is further configured to cause a third switch circuit that is connected to one of the first signal nodes that is connected to the first failed NTSV, among the third switch circuits, to be enabled, a fourth switch circuit that is connected to a second NTSV connected to the second failed NTSV, among the fourth switch circuits, to be enabled, and others of the third switch circuits and the fourth switch circuits to be disabled.

12. The semiconductor integrated circuit of claim 10, wherein the repair circuit is further configured to detect a third failed NTSV and a fourth failed NTSV from among the second NTSVs and cause a third switch circuit that is connected to one of the second signal nodes that is connected to the third failed NTSV, among the third switch circuits, to be enabled, a fourth switch circuit that is connected to one of the second signal nodes that is connected to the fourth failed NTSV, among the fourth switch circuits, to be enabled, and others of the third switch circuits and the fourth switch circuits to be disabled.

13. The semiconductor integrated circuit of claim 10,
wherein the repair circuit is further configured to detect the first failed NTSV and activate a first control signal,
wherein the first switch circuits and the third switch circuits comprise:
i PMOS transistors connected in parallel between an input node and an output node, the PMOS transistors being configured to transfer a signal of the input node to the output node based on activation of the first control signal; and
i NMOS transistors connected in parallel between the input node and the output node, the NMOS transistors being configured to transfer the signal of the input node to the output node based on the activation of the first control signal, and
wherein i is a natural number of 2 or more.

14. The semiconductor integrated circuit of claim 10,
wherein the repair circuit is further configured to detect the second failed NTSV and activate a second control signal,
wherein the second switch circuits and the fourth switch circuits comprise:
i PMOS transistors connected in parallel between an input node and an output node, the PMOS transistors being configured to transfer a signal of the input node to the output node based on activation of the second control signal; and
i NMOS transistors connected in parallel between the input node and the output node, the NMOS transistors being configured to transfer the signal of the input node to the output node based on the activation of the second control signal, and
wherein i is a natural number of 2 or more.

15. The semiconductor integrated circuit of claim 9, wherein the TSV repair units comprise n NTSVs and m RTSVs, wherein n is a natural number of 2 or more, and m<n.

16. A method of repairing a through-silicon via (TSV) of a semiconductor integrated circuit, the method comprising:
dividing a plurality of first TSVs of a first die into TSV repair units, wherein the TSV repair units comprise first normal TSVs (NTSVs) for signal transfer and a first redundant TSV (RTSV) for replacing a first failed NTSV from among the first NTSVs;
dividing a plurality of second TSVs of a second die stacked on the first die into the TSV repair units, wherein the plurality of second TSVs comprise second NTSVs and a second RTSV for the TSV repair units, and the second NTSVs and the second RTSV are respectively arranged opposite to the first NTSVs and the first RTSV and are respectively connected to the first NTSVs and the first RTSV by electrical connection structures;
detecting the first failed NTSV from among the first NTSVs; and
replacing the first failed NTSV by the first RTSV by using first switch circuits connected between the first RTSV and first signal nodes of the first die, the first signal nodes being respectively connected to the first NTSVs,
wherein, in the replacing of the first failed NTSV by the first RTSV, a first switch circuit that is connected to one of the first signal nodes that is connected to the first failed NTSV, among the first switch circuits, is enabled and others of the first switch circuits are disabled.

17. The method of claim 16, further comprising:
replacing the first failed NTSV by the first RTSV by using second switch circuits connected between the second RTSV and second signal nodes of the second die, the second signal nodes being respectively connected to the second NTSVs,
wherein a second switch circuit that is connected to a second NTSV connected to the first failed NTSV, among the second switch circuits, is enabled and others of the second switch circuits are disabled.

18. The method of claim 16, wherein the TSV repair units further comprise a third RTSV for replacing a second failed NTSV from among the first NTSVs of the first die, and
the second die further comprises a fourth RTSV arranged opposite to the third RTSV.

19. The method of claim 18, further comprising:
replacing the second failed NTSV by the third RTSV by using third switch circuits, which are connected between the third RTSV and the first signal nodes of the first die, and fourth switch circuits, which are connected between the fourth RTSV and second signal nodes of the second die,
wherein a third switch circuit that is connected to one of the first signal nodes that is connected to the second failed NTSV, among the third switch circuits, is enabled, a fourth switch circuit that is connected to a second NTSV connected to the second failed NTSV, among the fourth switch circuits, is enabled, and others of the third switch circuits and the fourth switch circuits are disabled.

20. The method of claim 16, further comprising:
activating a first control signal based on the first failed NTSV that is detected,
wherein the first switch circuits comprise i PMOS transistors and i NMOS transistors, which are connected in parallel, between an input node and an output node,
wherein the PMOS transistors and the NMOS transistors are configured to transfer a signal of the input node to the output node, based on activation of the first control signal, and
wherein i is a natural number of 2 or more.

21. (canceled)
